(19) United States
(12) Patent Application Publication
(10) Pub. No.: US 2021/0013016 A1
(43) Pub. Date: Jan. 14, 2021

(54) PROCESSING METHOD, PLACING PEDESTAL, PLASMA PROCESSING APPARATUS, AND RECORDING MEDIUM

(71) Applicant: Tokyo Electron Limited, Tokyo (JP)

(72) Inventor: Takashi TSUTO, Miyagi (JP)

(73) Assignee: Tokyo Electron Limited, Tokyo (JP)

(21) Appl. No.: 16/923,108

(22) Filed: Jul. 8, 2020

(30) Foreign Application Priority Data
Jul. 9, 2019 (JP) 2019-127378

(51) Int. Cl. H01J 37/32; H01L 21/67; H01L 21/687; H01L 21/683; H01L 21/3065; H01L 21/66; H01J 37/244

(52) U.S. Cl. CPC H01J 37/32715; H01L 21/67069; H01L 21/67253; H01L 21/68742; H01L 21/6833; H01L 21/3065; H01J 2237/3341; H01J 37/244; H01J 2237/2007; H01J 2237/24564; H01J 2237/20235; H01J 2237/0041; H01L 22/26

(57) ABSTRACT

A processing method includes a), b), and c). The a) includes measuring a load imposed on a lift pin when the lift pin lifts a processed substrate from an electrostatic chuck holding the substrate. The b) includes calculating a difference of the load is calculated based on the measured load and an initial load imposed on the lift pins when the lift pins lift the substrate without any residual adsorption force between the electrostatic chuck and the substrate. The c) includes exposing a surface of the electrostatic chuck to first plasma when the difference of the load is equal to or greater than a preset first threshold.

### CROSS-REFERENCE TO RELATED APPLICATIONS

The present application claims priority to and incorporates by reference the entire contents of Japanese Patent Application No. 2019-127378 filed in Japan on Jul. 9, 2019.

### FIELD

An exemplary embodiment disclosed herein relates to a processing method, a placing pedestal, a plasma processing apparatus, and a recording medium.

### BACKGROUND

In a process of a semiconductor wafer, for example, a semiconductor wafer subjected to the process is held onto an electrostatic chuck with an electrostatic force. When the process of the semiconductor wafer is finished, a direct-current (DC) voltage being supplied to the electrostatic chuck is released, so that the electrostatic force of the electrostatic chuck decreases, and the semiconductor wafer can be lifted from the electrostatic chuck using lift pins, for example.

As the process is performed to a plurality of semiconductor wafers, a reaction by-product (what is called deposit) that is an insulating body accumulates on the electrostatic chuck. The deposit accumulated on the electrostatic chuck then becomes charged by the electric potential supplied to the electrostatic chuck, and the deposit sometimes remains charged at the electric potential even after the DC voltage being supplied to the electrostatic chuck is released. When the deposit remains charged, an adsorption force corresponding to the electrostatic force remains exerted between the electrostatic chuck and the semiconductor wafer.

If the lift pins lift the semiconductor wafer with such a residual adsorption force exerted between the electrostatic chuck and the semiconductor wafer, the semiconductor wafer and the electrostatic chuck sometimes become rubbed against each other. If the semiconductor wafer and the electrostatic chuck are rubbed against each other, the deposit attached to the electrostatic chuck is scraped into particles, and the particles scatter and contaminate the semiconductor wafer. Furthermore, when the residual adsorption force is strong, the semiconductor wafer may be caused to jump or crack.

Known is a technology for preventing such problems is, for example, stopping the voltage supply to the electrostatic chuck after the plasma process, and calculating a counter voltage to be supplied to the electrode of the electrostatic chuck, based on a correlation between a current flowing out of the electrode of the electrostatic chuck and a torque applied to the lift pins. With this technology, the residual electric charge in the electrostatic chuck can be reduced by supplying a counter voltage to the electrostatic chuck, while introducing gas into a processing chamber and generating plasma therewith.

[Patent Literature 1] Japanese Laid-open Patent Publication No. 2013-161899

### SUMMARY

According to an aspect of a present disclosure, a processing method includes a), b), and c). The a) includes measuring a load imposed on a lift pin when the lift pin lifts a processed substrate from an electrostatic chuck holding the substrate. The b) includes calculating a difference of the load is calculated based on the measured load and an initial load imposed on the lift pins when the lift pins lift the substrate without any residual adsorption force between the electrostatic chuck and the substrate. The c) includes exposing a surface of the electrostatic chuck to first plasma when the difference of the load is equal to or greater than a preset first threshold.

### BRIEF DESCRIPTION OF DRAWINGS

FIG. 1 is a vertical sectional view illustrating one example of a plasma processing apparatus according to one embodiment disclosed herein;

FIG. 2 is an enlarged sectional view illustrating one example of a structure near the tip of a lift pin;

FIG. 3 is a block diagram illustrating one example of a functional configuration of a control device;

FIG. 4 is a flowchart illustrating one example of a residual adsorption force reducing method; and

FIG. 5 is a schematic illustrating one example of hardware of a computer implementing the functions of the control device.

### DESCRIPTION OF EMBODIMENTS

An exemplary embodiment of a processing method, a placing pedestal, a plasma processing apparatus, and a recording medium disclosed in the present application will be explained below in detail with reference to the accompanying drawings. The exemplary embodiment described below is not intended to limit the scope of the processing method, the placing pedestal, the plasma processing apparatus, and the recording medium disclosed herein in any way.

The adsorption force that remains on the electrostatic chuck after the plasma process is not limited to the adsorption force attributable to an electrostatic force. For example, when deposit containing a specific chemical element accumulates on the electrostatic chuck, the chemical element contained in the deposit and a chemical element contained in the semiconductor wafer disposed on the electrostatic chuck may become bonded by an intermolecular force. For example, when the deposit accumulated on the electrostatic chuck contains fluorine, a dangling bond of the fluorine sometimes becomes bonded to a dangling bond of silicon contained in the semiconductor wafer.

When the deposit accumulated on the electrostatic chuck and the semiconductor wafer are bonded by an intermolecular force, even if the electric potential of the deposit is decreased, the adsorption force between the electrostatic chuck and the semiconductor wafer based on the intermolecular force does not decrease. As the process is applied to a plurality of semiconductor wafers, the amount of deposit accumulated on the electrostatic chuck increases, and the number of dangling bonds of the fluorine contained in the deposit also increases. Therefore, the adsorption force based on the intermolecular force between the electrostatic chuck and the semiconductor wafer also increases.

When the adsorption force between the electrostatic chuck and the semiconductor wafer increases, jumping, cracking, or the like of the semiconductor wafer occurs. When a crack or the like of the semiconductor wafer is observed, the electrostatic chuck may be cleaned, so that the residual adsorption force between the electrostatic chuck and the semiconductor wafer will be reduced. However, the semiconductor wafer on which a crack or the like is observed will be handled as a defective product, and the semiconductor wafer will be wasted. Therefore, there is a demand for a method for reducing the residual adsorption force on the electrostatic chuck before the cracks and the like are observed on the semiconductor wafer.

Therefore, the present disclosure provides a technology capable of reducing the adsorption force remaining on the electrostatic chuck.

Configuration of Plasma Processing Apparatus 1

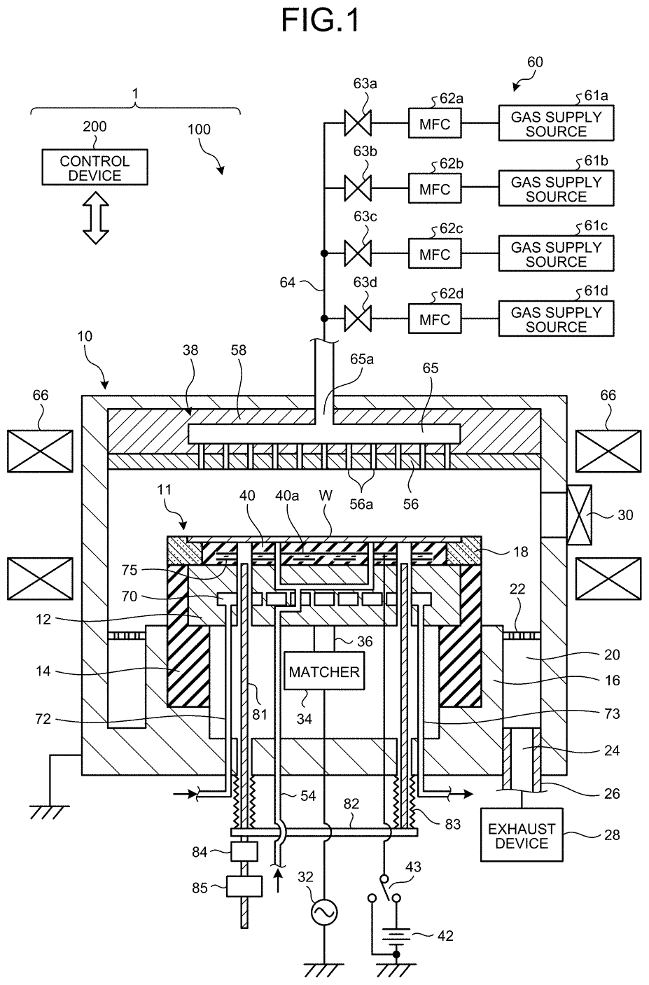

FIG. 1 is a vertical sectional view illustrating one example of a plasma processing apparatus 1 according to one embodiment disclosed herein. The plasma processing apparatus 1 according to this embodiment is configured as a reactive ion etching (RIE) plasma processing apparatus, for example. This plasma processing apparatus 1 includes a main unit 100 and a control device 200.

The main unit 100 has a processing container 10 made of a metal such as aluminum or stainless steel, and having a substantially cylindrical shape. The processing container 10 is grounded. In the processing container 10, a semiconductor wafer W that is one example of a substrate is subjected to a plasma process such as an etching process.

A placing pedestal 11 on which the semiconductor wafer W is placed is provided inside the processing container 10. The placing pedestal 11 includes a platen 12, an electrostatic chuck 40, a plurality of lift pins 81, a load sensor 84, and a driving unit 85. The platen 12 is made of aluminum, for example, and is supported inside of a tubular support 16 extending vertically from the bottom of the processing container 10, via an insulating tubular holder unit 14. The electrostatic chuck 40 is disposed on the upper surface of the platen 12. On the upper surface of the tubular holder unit 14, an edge ring 18 made of silicon, for example, is disposed in a manner surrounding the electrostatic chuck 40. The edge ring 18 is sometimes called a focus ring.

An exhaust route 20 is provided between the inner wall of the processing container 10 and the outer wall of the tubular support 16. An annular baffle plate 22 is mounted on the exhaust route 20. An exhaust port 24 is provided at a bottom part of the exhaust route 20. An exhaust device 28 is connected to the exhaust port 24, via an exhaust pipe 26. The exhaust device 28 includes a vacuum pump not illustrated, and is capable of reducing the pressure inside of the processing container 10 to a desirable degree of vacuum. On the side wall of the processing container 10, a gate valve 30 that opens and closes when the semiconductor wafer W is to be carried in and out of the processing container 10 is provided.

A high-frequency power source 32 for generating plasma is electrically connected to the platen 12 via a power supply rod 36 and a matcher 34. The high-frequency power source 32 supplies high-frequency power at a frequency of 60 MHz, for example, to the platen 12. The platen 12 also serves as a lower electrode. On the ceiling of the processing container 10, a shower head 38 is provided. The shower head 38 also serves as an upper electrode facing the platen 12.

On the upper surface of the platen 12, the electrostatic chuck 40 for holding the semiconductor wafer W with an electrostatic adsorption force is provided. The electrostatic chuck 40 has a structure in which an electrode 40a that is a conductive film is sandwiched between a pair of insulating layers or insulating sheets. A DC power source 42 is connected to the electrode 40a via a switch 43. The switch 43 switches to connect the electrode 40a to the DC power source 42 or to a ground potential. When the DC power source 42 is connected to the electrode 40a, the voltage from the DC power source 42 is supplied to the electrode 40a, and an electrostatic force is generated on the surface of the electrode 40a. With the electrostatic force, the semiconductor wafer W disposed on the electrostatic chuck 40 is adsorbed and held onto the upper surface of the electrostatic chuck 40.

When the plasma process of the semiconductor wafer W is finished, the switch 43 connects the electrode 40a to the ground potential, so that the electric potential remaining on the electrode 40a is released. However, there are sometimes cases in which, although the electrode 40a is connected to the ground potential, the adsorption force between the electrostatic chuck 40 and the semiconductor wafer W does not decrease, because the electric potential resultant of the plasma process remains in the semiconductor wafer W.

Furthermore, when deposit containing a specific chemical element becomes accumulated between the electrostatic chuck 40 and the semiconductor wafer W, the chemical element contained in the deposit and a chemical element contained in the semiconductor wafer W may become bonded by an intermolecular force. For example, when the deposit accumulated on the electrostatic chuck 40 contains fluorine, a dangling bond of the fluorine sometimes becomes bonded to a dangling bond of silicon contained in the semiconductor wafer W. When a dangling bond of a chemical element contained in the deposit become bonded to a dangling bond of a chemical element contained in the semiconductor wafer W, an adsorption force is generated between the electrostatic chuck 40 and the semiconductor wafer W, based on the intermolecular force. When the plasma process of the semiconductor wafer W is repeated, an increased amount of the deposit becomes accumulated between the electrostatic chuck 40 and the semiconductor wafer W, and the adsorption force based on the intermolecular force between the electrostatic chuck 40 and the semiconductor wafer W also increases.

If the residual adsorption force between the electrostatic chuck 40 and the semiconductor wafer W increases, the semiconductor wafer W may jump or become damaged as the processed semiconductor wafer W is lifted by lift pins 81, which will be described later. If the semiconductor wafer W jumps, the semiconductor wafer W may become offset from a preset position, or a reaction by-product may fly around in the processing container 10 and become attached to the semiconductor wafer W. To address these issues, when the residual adsorption force between the electrostatic chuck 40 and the semiconductor wafer W is strong, a process for reducing the residual adsorption force between the electrostatic chuck 40 and the semiconductor wafer W is performed. This process for reducing the residual adsorption force between the electrostatic chuck 40 and the semiconductor wafer W will be described later.

The platen 12 and the electrostatic chuck 40 are provided with a pipe 54 for supplying heat-transfer gas such as He gas or Ar gas between the semiconductor wafer W and the electrostatic chuck 40. By controlling the pressure of the heat-transfer gas supplied between the semiconductor wafer W and the electrostatic chuck 40, the heat transfer rate between the electrostatic chuck 40 and the semiconductor wafer W can be controlled.

The shower head 38 has an electrode plate 56 and an electrode support 58. The electrode plate 56 has a plurality of gas holes 56a passing therethrough in the thickness direction of the electrode plate 56. The electrode support 58 supports the electrode plate 56 in a removable manner. Inside of the electrode support 58, a buffer chamber 65 is provided. A gas inlet port 65a communicating with the buffer chamber 65 is provided to the upper part of the electrode support 58. A gas supply mechanism 60 is connected to the gas inlet port 65a via a pipe 64.

The gas supply mechanism 60 includes gas supply sources 61a to 61d, mass flow controllers (MFCs) 62a to 62d, and valves 63a to 63d. The gas supply source 61a is a source for supplying processing gas for etching, for example. The gas supply source 61b is a source for supplying nitrogen gas, for example. The gas supply source 61c is a source for supplying oxygen gas, for example. The gas supply source 61d is a source for supplying CF4 gas, for example.

The MFC 62a controls the flow volume of the processing gas supplied from the gas supply source 61a, and supplies the processing gas having the flow volume controlled to the shower head 38 via the valve 63a and the pipe 64. The MFC 62b controls the flow volume of the nitrogen gas supplied from the gas supply source 61b, and supplies the nitrogen gas having the flow volume controlled to the shower head 38 via the valve 63b and the pipe 64. The MFC 62c controls the flow volume of the oxygen gas supplied from the gas supply source 61c, and supplies the oxygen gas having the flow volume controlled to the shower head 38 via the valve 63c and the pipe 64. The MFC 62d controls the flow volume of the CF4 gas supplied from the gas supply source 61d, and supplies CF4 gas having the flow volume controlled to the shower head 38 via the valve 63d and the pipe 64.

The gas supplied to the shower head 38 via the pipe 64 becomes diffused inside the buffer chamber 65, and is supplied into the processing space between the shower head 38 and the placing pedestal 11, in a shower-like fashion, via the gas holes 56a provided to the electrode plate 56.

Provided inside the platen 12 are a plurality of lift pins 81 (e.g., three) for moving the semiconductor wafer W up and down to enable the semiconductor wafer W to be received from and passed onto an external transfer arm not illustrated. The power from the driving unit 85 such as a motor, transmitted via a joint member 82, moves the lift pins 81 up and down, in a manner passing through the electrostatic chuck 40. Provided between the joint member 82 and the driving unit 85 is the load sensor 84 for measuring the load imposed on the lift pins 81 when the lift pins 81 push up the semiconductor wafer W. The load sensor 84 is one example of a first sensor. The load sensor 84 is a load cell, for example. A bellows 83 is provided on the lower part of each of the lift pins 81. With this, the air tightness between the vacuum side and the atmosphere side of the processing container 10 is maintained.

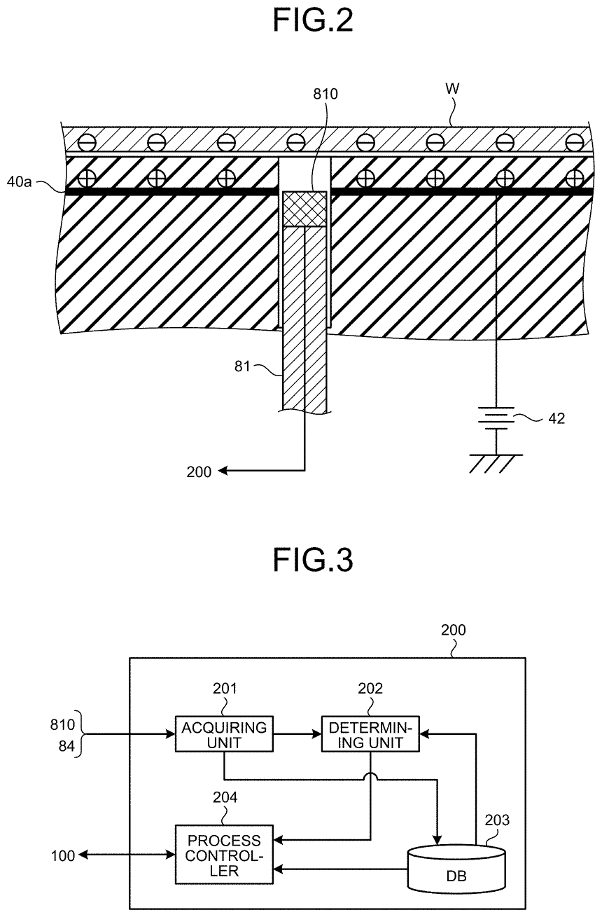

FIG. 2 is an enlarged sectional view illustrating one example of a structure near the tip of a lift pin 81. An electric charge sensor 810 for measuring the electric charge in the semiconductor wafer W is provided to the tip of the lift pin 81. The electric charge sensor 810 measures the electric charge in the semiconductor wafer W when the lift pins 81 push up the processed semiconductor wafer W, and outputs the measurement result to the control device 200. The electric charge sensor 810 is one example of a second sensor.

In this embodiment, the electric charge sensor 810 is provided to the tip of one of the lift pins 81. The electric charge sensor 810 may also be provided to the tip of each of the lift pins 81. When the electric charge sensor 810 is provided to the tip of each of the lift pins 81, the control device 200 uses the highest or an average value of the electric charges measured by the respective electric charge sensors 810, as the electric charge. Furthermore, when the electrostatic chuck 40 is divided into a plurality of zones, and each of the zones is provided with one electrode 40a, it is preferable for each of the zones to be provided with at least one electric charge sensor 810. In such a configuration, too, the control device 200 uses the highest or an average value of the electric charges measured by the respective electric charge sensors 810, as the electric charge.

A magnet 66 extending in an annular shape or a concentric shape is disposed around the processing container 10. In the processing space between the shower head 38 and the placing pedestal 11 in the processing container 10, a radio frequency (RF) field is generated by the high-frequency power source 32 in the vertical direction, so that high-density plasma is generated near the surface of the semiconductor wafer W, using desirable gas.

Inside of the platen 12, a channel 70 through which coolant is passed is provided. A chiller unit, not illustrated, supplies the coolant having the temperature controlled, through a pipe 72 and a pipe 73, in a manner circulating through the channel 70. A heater 75 is embedded inside of the electrostatic chuck 40. An alternating-current (AC) power source not illustrated applies a desirable AC voltage to the heater 75. With the cooling by the coolant circulating through the channel 70 and the heating by the heater 75, the temperature of the semiconductor wafer W on the electrostatic chuck 40 is adjusted to a desirable temperature. It is also possible to omit the heater 75. Furthermore, it is also possible to provide the heater 75 between the electrostatic chuck 40 and the platen 12.

The control device 200 controls the units included in the main unit 100. For example, the control device 200 controls the gas supply mechanism 60, the exhaust device 28, the heater 75, the DC power source 42, the switch 43, the matcher 34, the high-frequency power source 32, the driving unit 85, and the chiller unit.

In the plasma processing apparatus 1, before the plasma process such as etching to the semiconductor wafer W is performed, to begin with, the gate valve 30 is opened, and the semiconductor wafer W held on the transfer arm, not illustrated, is carried into the processing container 10. The lift pins 81 protruding from the surface of the electrostatic chuck 40 then lift the semiconductor wafer W from the transfer arm, and the semiconductor wafer W is passed from the transfer arm onto the lift pins 81. After the transfer arm evacuates from the processing container 10, the lift pins 81 are moved down, so that the semiconductor wafer W is placed on the electrostatic chuck 40. The gate valve 30 is then closed.

The DC power source 42 then supplies the DC voltage to the electrode 40a, and the semiconductor wafer W is adsorbed and held onto the upper surface of the electrostatic chuck 40. The exhaust device 28 then exhausts the gas inside of the processing container 10, and the gas supply mechanism 60 supplies the processing gas for etching into the processing container 10 at a predetermined flow volume, and the pressure inside of the processing container 10 is adjusted. The heat-transfer gas is then supplied between the semiconductor wafer W and the electrostatic chuck 40. The high-frequency power source 32 then supplies predetermined high-frequency power to the platen 12. With the high-frequency power supplied from the high-frequency power source 32, the shower-like processing gas for etching, introduced via the shower head 38, is turned into plasma. In this manner, plasma is generated inside of the processing space between the shower head 38 and the platen 12, and the semiconductor wafer W is etched with the radicals and the ions contained in the generated plasma.

After the plasma process is finished, the supply of the heat-transfer gas is stopped, and the voltage supply to the electrode 40a of the electrostatic chuck 40 is also stopped, before the semiconductor wafer W is removed from the electrostatic chuck 40. The lift pins 81 are then moved up, to lift the semiconductor wafer W from the electrostatic chuck 40. The gate valve 30 is then opened, and the semiconductor wafer W is passed onto the transfer arm not illustrated, and carried out of the processing container 10.

When the lift pins 81 lift the semiconductor wafer W, the load sensor 84 measures the load L imposed on the lift pins 81, and the electric charge sensor 810 measures an electric charge Q in the semiconductor wafer W. The measured load L and electric charge Q are then output to the control device 200.

Configuration of Control Device 200

FIG. 3 is a block diagram illustrating one example of a functional configuration of the control device 200. The control device 200 includes an acquiring unit 201, a determining unit 202, a database (DB) 203, and a process controller 204.

The DB 203 stores therein an initial load L₀, an initial electric charge Q₀, a load threshold Lₜₕ, and a charge threshold Qₜₕ. The initial load L₀ is a load imposed on the lift pins 81 when the lift pins 81 lift the semiconductor wafer W without any residual adsorption force between the electrostatic chuck 40 and the semiconductor wafer W. The initial load L₀ is measured by the load sensor 84 when the lift pins 81 push up the semiconductor wafer W, before the process is performed, for example.

The initial electric charge Q₀ is the electric charge in the semiconductor wafer W measured by the electric charge sensor 810 while the semiconductor wafer W is not charged. The initial electric charge Q₀ is measured by the electric charge sensor 810 when the lift pins 81 lift the semiconductor wafer W, before the process is performed, for example.

The load threshold Lₜₕ is a value smaller than the difference between the initial load L₀ and a load at which the semiconductor wafer W jumps or cracks when the lift pins 81 lift the semiconductor wafer W. The load threshold Lₜₕ is one example of a first threshold. The charge threshold Qₜₕ is a value smaller than a difference between the initial electric charge Q₀ and the electric charge at which the semiconductor wafer W jumps or cracks when the lift pins 81 lift the semiconductor wafer W.

The load threshold Lₜₕ is set to a value such as 0.5 [kgf]. The charge threshold Qₜₕ is set to a value such as 0.5 μ[C]. Recipe data is also stored in the DB 203 in advance.

The acquiring unit 201 acquires the load L measured by the load sensor 84 before the process is performed, and stores the acquired load L in the DB 203 as the initial load L₀. The acquiring unit 201 also acquires the electric charge Q measured by the electric charge sensor 810 before the process is performed, and stores the acquired electric charge Q in the DB 203 as the initial electric charge Q₀. The acquiring unit 201 also acquires the load L measured by the load sensor 84 after the plasma process is performed, and outputs the acquired load L to the determining unit 202. The acquiring unit 201 also acquires the electric charge Q measured by the electric charge sensor 810 after the plasma process is performed, and outputs the acquired electric charge Q to the determining unit 202.

When the load L and the electric charge Q are received from the acquiring unit 201, the determining unit 202 acquires the initial load L₀, the load threshold Lₜₕ, the initial electric charge Q₀, and the charge threshold Qₜₕ from the DB 203. The determining unit 202 then determines whether a difference ΔQ that is an electric charge Q resultant of subtracting the initial electric charge Q₀ from the electric charge Q is greater than the charge threshold Qₜₕ. If the difference ΔQ is equal to or less than the charge threshold Qₜₕ, the determining unit 202 determines whether the difference ΔL that is a load L resultant of subtracting the initial load L₀ from the load L is greater than the load threshold Lₜₕ. If the difference ΔL is greater than the load threshold Lₜₕ, that is, if the load L is high but the electric charge Q is not very high, the determining unit 202 gives an instruction for executing a plasma process A to the process controller 204.

The plasma process A is a process for reducing the adsorption force attributable to bonding between a dangling bond of a specific chemical element contained in the deposit accumulated between the electrostatic chuck 40 and the semiconductor wafer W, and a dangling bond of a chemical element contained in the semiconductor wafer W. In the plasma process A, after the semiconductor wafer W is carried out, plasma is generated in the processing container 10, so that a chemical element contained in the plasma terminates the dangling bonds of a chemical element contained in the deposit accumulated between the electrostatic chuck 40 and the semiconductor wafer W. For example, nitrogen atoms contained in the plasma terminate the dangling bonds of fluorine contained in the deposit. In this manner, the adsorption force attributable to the intermolecular force between the electrostatic chuck 40 and the semiconductor wafer W is reduced.

The plasma process A is a plasma process that uses first plasma generated by turning nitrogen-containing gas into plasma, and is performed under the following conditions, for example:

Gas species: nitrogen gas

Flow volume: 300 sccm

Time: 10 seconds

If the difference ΔQ is greater than the charge threshold Qₜₕ, the determining unit 202 determines whether the difference ΔL is greater than the load threshold Lₜₕ. If the difference ΔL is equal to or smaller than the load threshold Lₜₕ, that is, if the electric charge Q is high but the load L is not very high, the determining unit 202 gives an instruction for performing a plasma process B to the process controller 204.

The plasma process B is a process for reducing the adsorption force attributable to the electric potential of the charged deposit accumulated between the electrostatic chuck 40 and the semiconductor wafer W, the deposit being charged in the plasma process. In the plasma process B, after the semiconductor wafer W is carried out, plasma is generated in the processing container 10, and the electric potential of the charged deposit accumulated between the electrostatic chuck 40 and the semiconductor wafer W is removed by the ions and the electrons contained in the plasma. In this manner, the adsorption force attributable to the electrostatic force of the charged deposit between the electrostatic chuck 40 and the semiconductor wafer W is reduced.

The plasma process B is a plasma process that uses second plasma generated by turning oxygen- or argon-containing gas into plasma, and is performed under the following conditions, for example:

Gas species: oxygen gas and CF4 gas

Flow volume: oxygen gas=1350 sccm, CF4 gas=150 sccm

Time: 25 seconds

When the load L is not very high, the plasma process B does not necessarily need to be performed, from the viewpoint of reducing the adsorption force. However, when the electric charge Q of the deposit is high, there are cases in which electric discharge takes place between the electrostatic chuck 40 and the semiconductor wafer W, as the semiconductor wafer W is lifted from the electrostatic chuck 40, and damages the electrostatic chuck 40, the semiconductor wafer W, or the like. Furthermore, if the electric charge Q of the deposit is high, the semiconductor wafer W becomes charged in the polarity opposite to that of the deposit. The charged semiconductor wafer W may then attract particles in the processing container 10, and be contaminated thereby. Therefore, by performing the plasma process B when the electric charge Q is high although the load L is not very high, the electric charge Q of the deposit is reduced.

In the plasma process B may be a process of turning the oxygen gas at 650 sccm into plasma, without using CF4 gas. The plasma process B may also be a process of turning the argon gas at 1000 sccm into plasma, without using the CF4 gas and the oxygen gas. The processing time with the use of argon gas is set to 10 seconds, for example.

If the difference ΔL is greater than the load threshold Lₜₕ, that is, if the electric charge Q as well as the load L are high, the determining unit 202 gives an instruction for performing a plasma process C to the process controller 204. The plasma process C is a process for reducing the adsorption force attributable to the intermolecular force in the deposit, as well as the adsorption force attributable to the electrostatic force of the charged deposit. In this embodiment, the plasma process C is a process for performing both of the plasma process A and the plasma process B described above, for example. In the plasma process C, after the plasma process A is performed, the plasma process B is performed. In the plasma process C, it is also possible for the plasma process A to be performed after the plasma process B is performed. In this manner, it is possible to terminate the dangling bonds of the chemical element contained in the deposit, as well as to remove the electric potential of the charged deposit.

The process controller 204 causes the main unit 100 to perform a plasma process specified in a recipe, by controlling the units included in the main unit 100 based on the corresponding recipe stored in the DB 203. When an instruction for performing the plasm process A, B, or C is received from the determining unit 202, the process controller 204 reads the corresponding recipe from the DB 203, and controls the units included in the main unit 100, in accordance with the read recipe.

Residual Adsorption Force Reducing Method

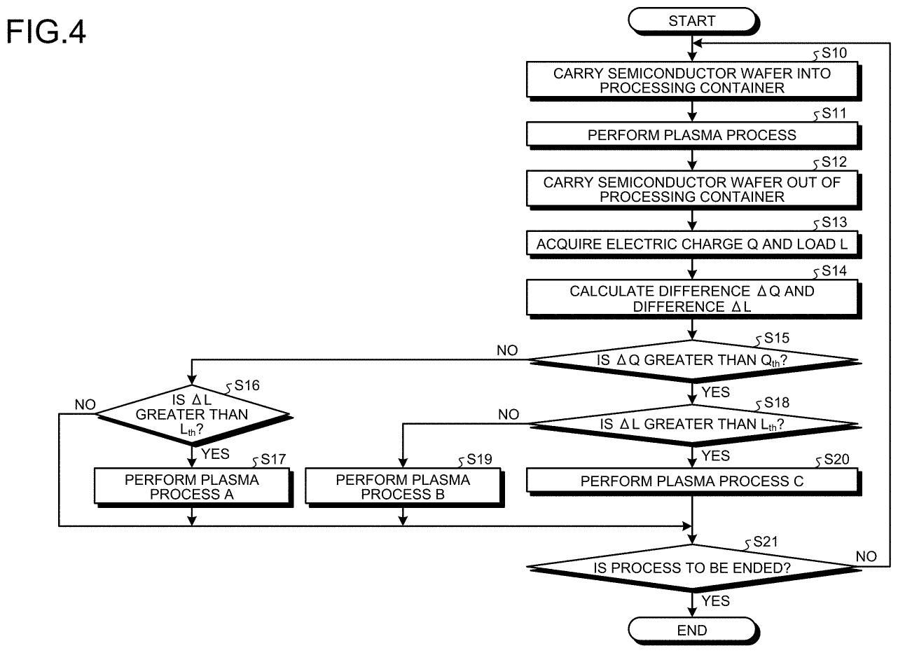

FIG. 4 is a flowchart illustrating one example of a residual adsorption force reducing method. The residual adsorption force reducing method illustrated in FIG. 4 is implemented by the main unit 100 operating under the control of the control device 200. The residual adsorption force reducing method is one example of a processing method. Before performing the process illustrated in FIG. 4, the load sensor 84 measures the initial load L₀ imposed on the lift pins 81 using a dummy wafer or the like, and the electric charge sensor 810 measures the initial electric charge Q₀ of the semiconductor wafer W. The acquiring unit 201 in the control device 200 then acquires the measured initial load L₀ and the initial electric charge Q₀, and stores these values in the DB 203.

To begin with, the semiconductor wafer W is carried into the processing container 10 (S10). At Step S10, the gate valve 30 is opened, and the semiconductor wafer W held on the transfer arm, not illustrated, is carried into the processing container 10. The lift pins 81 protruding from the surface of the electrostatic chuck 40 then lift the semiconductor wafer W from the transfer arm, and the semiconductor wafer W is passed from the transfer arm onto the lift pins 81. After the transfer arm evacuates from the processing container 10, the lift pins 81 are moved down, and the semiconductor wafer W is placed on the electrostatic chuck 40. The gate valve 30 is then closed. The DC voltage is then supplied from the DC power source 42 to the electrode 40a, and the semiconductor wafer W is adsorbed and held onto the upper surface of the electrostatic chuck 40.

The plasma process such as etching is then applied to the semiconductor wafer W having been carried into the processing container 10 (S11). At Step S11, the exhaust device 28 exhausts the gas in the processing container 10, and the gas supply mechanism 60 supplies the processing gas for etching into the processing container 10 at a predetermined flow volume, and the pressure inside of the processing container 10 is adjusted. The heat-transfer gas is then supplied between the semiconductor wafer W and the electrostatic chuck 40. The high-frequency power source 32 then supplies predetermined high-frequency power to the platen 12. The processing gas for etching is introduced via the shower head 38 in a shower-like fashion, and is turned into plasma by the high-frequency power supplied from the high-frequency power source 32. In this manner, plasma is generated in the processing space between the shower head 38 and the platen 12, and the semiconductor wafer W is applied with the plasma process such as etching by the radicals and ions contained in the generated plasma.

The semiconductor wafer W applied with the plasma process is then carried out of the processing container 10 (S12). At Step S12, the supply of the heat-transfer gas is stopped, and the supply of the voltage to the electrode 40a of the electrostatic chuck 40 is also stopped. The lift pins 81 are then moved up to lift the semiconductor wafer W from the electrostatic chuck 40. At this time, the load sensor 84 measures the load L imposed on the lift pins 81, and the electric charge sensor 810 measures the electric charge Q in the semiconductor wafer W. The gate valve 30 is then opened, and the semiconductor wafer W is passed onto the transfer arm, not illustrated, having entered the processing container 10, and the semiconductor wafer W is carried out of the processing container 10. Step S12 is one example of a first measuring step and a second measuring step.

The load L measured by the load sensor 84 and the electric charge Q measured by the electric charge sensor 810 are then output to the control device 200. The acquiring unit 201 in the control device 200 then acquires the measured load L and electric charge Q (S13). The acquiring unit 201 then outputs the acquired load L and electric charge Q to the determining unit 202.

The determining unit 202 then calculates the differences ΔQ and ΔL (S14). For example, when the load L and the electric charge Q are received from the acquiring unit 201, the determining unit 202 acquires the initial load L₀, the load threshold Lₜₕ, the initial electric charge Q₀, and the charge threshold Qₜₕ from the DB 203. The determining unit 202 then calculates the value resultant of subtracting the initial electric charge Q₀ from the electric charge Q as the difference ΔQ of the electric charge Q, and calculates the value resultant of subtracting the initial load L₀ from the load L as the difference ΔL of the load L. The Step S14 is one example of a first calculating step and a second calculating step.

The determining unit 202 then determines whether the difference ΔQ is greater than the charge threshold Qₜₕ (S15). If the difference ΔQ is equal to or less than the charge threshold Qₜₕ (No at S15), the determining unit 202 determines whether the difference ΔL is greater than the load threshold Lₜₕ (S16). If the difference ΔL is equal to or smaller than the load threshold Lₜₕ (No at S16), that is, if neither the electric charge Q nor the load L is very high, the process illustrated at Step S21 is performed.

If the difference ΔL is greater than the load threshold Lₜₕ (Yes at S16), that is, if the load L is high but the electric charge Q is not very high, the determining unit 202 gives an instruction for performing the plasma process A to the process controller 204. The process controller 204 reads the recipe corresponding to the plasma process A from the DB 203, and performs the plasma process A by controlling the units included in the main unit 100 in accordance with the read recipe (S17). The plasma process A is one example of a first plasma processing step. The process illustrated at Step S21 is then performed.

If the difference ΔQ is greater than the charge threshold Qₜₕ (Yes at S15), the determining unit 202 determines whether the difference ΔL is greater than the load threshold Lₜₕ (S18). If the difference ΔL is equal to or smaller than the load threshold Lₜₕ (No at S18), that is, if the electric charge Q is high but the load L is not very high, the determining unit 202 gives an instruction for performing the plasma process B to the process controller 204. The process controller 204 reads the recipe corresponding to the plasma process B from the DB 203, and performs the plasma process B by controlling the units included in the main unit 100 in accordance with the read recipe (S19). The plasma process B is one example of a second plasma processing step. The process illustrated at Step S21 is then performed.

If the difference ΔL is greater than the load threshold Lₜₕ (Yes at S18), that is, if the electric charge Q as well as the load L are high, the determining unit 202 gives an instruction for performing the plasma process C to the process controller 204. The process controller 204 reads the recipe corresponding to the plasma process C from the DB 203, and performs the plasma process C by controlling the units included in the main unit 100 in accordance with the read recipe (S20).

The process controller 204 determines whether the process is to be ended (S21). If the process is to be continued (No at S21), the process illustrated at Step S10 is performed again. If the process is to be ended (Yes at S21), the residual adsorption force reducing method illustrated in this flowchart is ended.

Hardware

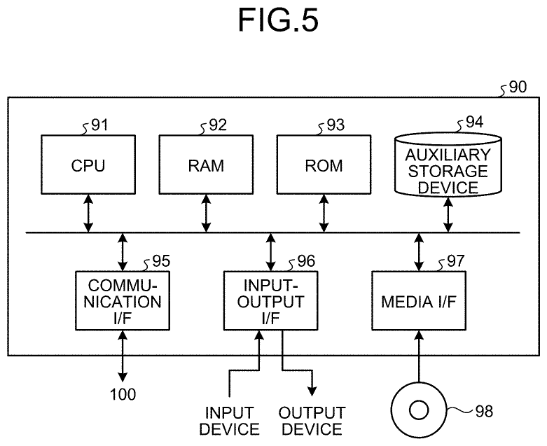

The control device 200 is implemented by a computer 90 having a configuration illustrated in FIG. 5, for example. FIG. 5 is a schematic illustrating one example of the computer 90 for implementing the functions of the control device 200. The computer 90 includes a central processing unit (CPU) 91, a random-access memory (RAM) 92, a read-only memory (ROM) 93, an auxiliary storage device 94, a communication interface (I/F) 95, an input-output I/F 96, and a media I/F 97.

The CPU 91 operates based on a computer program stored in the ROM 93 or the auxiliary storage device 94, and controls each unit. The ROM 93 stores therein a boot program executed by the CPU 91 when the computer 90 is started, and a computer program that is dependent on the hardware of the computer 90, for example.

The auxiliary storage device 94 is a hard disk drive (HDD) or a solid state drive (SSD), for example, and stores therein the computer program executed by the CPU 91, and data used by the computer program, for example. The CPU 91 reads the computer program from the auxiliary storage device 94 and loads the computer program onto the RAM 92 to execute the loaded program.

The communication I/F 95 communicates with the main unit 100 via a communication line, such as a local area network (LAN). The communication I/F 95 receives data from the main unit 100, transmits the data to the CPU 91 via the communication line, and also transmits the data generated by the CPU 91 to the main unit 100 via the communication line.

The CPU 91 controls an input device such as a keyboard and an output device such as a display via the input-output I/F 96. The CPU 91 acquires signals entered from the input device via the input-output I/F 96, and sends the signals to the CPU 91. The CPU 91 also outputs generated data to the output device via the input-output I/F 96.

The media I/F 97 reads the computer program or the data stored in a recording medium 98, and stores the computer program or the data in the auxiliary storage device 94. Examples of the recording medium 98 include an optical recording medium such as a digital versatile disc (DVD) and a phase change rewritable disk (PD), a magneto-optical recording medium such as a magneto-optical (MO) disk, a tape medium, a magnetic recording medium, or a semiconductor memory.

The CPU 91 executes a computer program loaded onto the RAM 92 to implement the functions of the acquiring unit 201, the determining unit 202, and the process controller 204. The data in the DB 203 is stored in the auxiliary storage device 94.

The CPU 91 executes a computer program read from the recording medium 98 and stored in the auxiliary storage device 94, but as another example, the CPU 91 may also acquire the computer program from another device via the communication line, and execute the acquired computer program.

One exemplary embodiment is explained above. As described above, the processing method according to the embodiment includes the first measuring step, the first calculating step, and the first plasma processing step. At the first measuring step, the load L imposed on the lift pins 81 when the lift pins 81 lift the processed semiconductor wafer W from the electrostatic chuck 40 holding the semiconductor wafer W is measured. At the first calculating step, the difference ΔL of the load L is calculated based on the measured load L, and the initial load L₀ imposed on the lift pins 81 when the lift pins 81 lift the semiconductor wafer W without any residual adsorption force between the electrostatic chuck 40 and the semiconductor wafer W. At the first plasma processing step, if the difference ΔL of the load L is equal to or greater than a preset load threshold Lₜₕ, the surface of the electrostatic chuck 40 is exposed to the first plasma. In this manner, it is possible to reduce the residual adsorption force attributable to the intermolecular force between the electrostatic chuck 40 and the semiconductor wafer W.

Furthermore, in the embodiment described above, the load threshold Lₜₕ is a value smaller than a difference between the initial load L₀ and the load L imposed on the lift pins 81 when the semiconductor wafer W jumps as the lift pins 81 lift the semiconductor wafer W. In this manner, it is possible to prevent jumping of the semiconductor wafer W when the lift pins 81 lift the semiconductor wafer W, because of the residual adsorption force.

Furthermore, in the embodiment described above, the first plasma is plasma generated by turning nitrogen-containing gas into plasma. In this manner, it is possible to reduce the residual adsorption force attributable to the intermolecular force between the electrostatic chuck 40 and the semiconductor wafer W.

The processing method according to the embodiment described above includes the second measuring step, the second calculating step, and the second plasma processing step. At the second measuring step, the electric charge sensor 810 provided to the tip of the lift pin 81 on the side being brought into contact with the semiconductor wafer W measures the electric charge Q in the semiconductor wafer W, when the lift pins 81 lift the processed semiconductor wafer W from the electrostatic chuck 40. At the second calculating step, the difference ΔQ of the electric charge Q is calculated based on the measured electric charge Q, and the initial electric charge Q₀ measured by the electric charge sensor 810 while the semiconductor wafer W is not charged. At the second plasma processing step, if the difference ΔQ of the electric charge Q is equal to or greater than a preset charge threshold Qₜₕ, the surface of the electrostatic chuck 40 is exposed to the second plasma. In this manner, it is possible to reduce the adsorption force attributable to the residual electrostatic force between the electrostatic chuck 40 and the semiconductor wafer W.

Furthermore, in the embodiment described above, the second plasma is plasma generated by turning oxygen- or argon-containing gas into plasma. In this manner, it is possible to reduce the adsorption force attributable to the residual electrostatic force between the electrostatic chuck 40 and the semiconductor wafer W.

The placing pedestal 11 according to the embodiment described above includes the electrostatic chuck 40, the lift pins 81, the load sensor 84, and the driving unit 85. The electrostatic chuck 40 is configured to hold the semiconductor wafer W. The lift pins 81 pass through the electrostatic chuck 40, and lift the semiconductor wafer W held on the electrostatic chuck 40 from the electrostatic chuck 40. The driving unit 85 moves the lift pins 81 up and down. The load sensor 84 measures the load imposed on the lift pins 81 when the semiconductor wafer W is lifted from the electrostatic chuck 40. In this manner, it is possible to detect an increase in the residual adsorption force attributable to the intermolecular force between the electrostatic chuck 40 and the semiconductor wafer W.

Furthermore, in the embodiment described above, the electric charge sensor 810 for measuring electric charge in the semiconductor wafer W is provided to the tip of the lift pin 81, the tip being on the side brought into contact with the semiconductor wafer W. In this manner, it is possible to detect an increase in the adsorption force attributable to the residual electrostatic force between the electrostatic chuck 40 and the semiconductor wafer W.

The plasma processing apparatus 1 according to the embodiment described above includes the processing container 10, the electrostatic chuck 40, the lift pins 81, the load sensor 84, the driving unit 85, and the control device 200. The electrostatic chuck 40 is provided inside the processing container 10, and configured to hold the semiconductor wafer W. The lift pins 81 pass through the electrostatic chuck 40, and lift the semiconductor wafer W held on the electrostatic chuck 40 from the electrostatic chuck 40. The driving unit 85 moves the lift pins up and down. The load sensor 84 measures the load imposed on the lift pins 81 when the semiconductor wafer W is lifted from the electrostatic chuck 40. The control device 200 performs the first measuring step, the first calculating step, and the first plasma processing step. At the first measuring step, the load L imposed on the lift pins 81 when the lift pins 81 lift the processed semiconductor wafer W from the electrostatic chuck 40 holding the semiconductor wafer W is measured with the load sensor 84. At the first calculating step, the difference ΔL of the load L is calculated based on the measured load L, and the initial load L₀ imposed on the lift pins 81 when the lift pins 81 lift the semiconductor wafer W without any residual adsorption force between the electrostatic chuck 40 and the semiconductor wafer W. At the first plasma processing step, if the difference ΔL of the load L is equal to or greater than a preset load threshold Lₜₕ, the surface of the electrostatic chuck 40 is exposed to the first plasma. In this manner, it is possible to reduce the residual adsorption force attributable to the intermolecular force between the electrostatic chuck 40 and the semiconductor wafer W.

A non-transitory computer readable recording medium that stores a program according to the embodiment causes the plasma processing apparatus 1 to execute the first measuring step, the first calculating step, and the first plasma processing step. At the first measuring step, the load L imposed on the lift pins 81 when the lift pins 81 lift the processed semiconductor wafer W from the electrostatic chuck 40 holding the semiconductor wafer W is measured. At the first calculating step, the difference ΔL of the load L is calculated based on the measured load L, and the initial load L₀ imposed on the lift pins 81 when the lift pins 81 lift the semiconductor wafer W without any residual adsorption force between the electrostatic chuck 40 and the semiconductor wafer W. At the first plasma processing step, if the difference ΔL of the load L is equal to or greater than a preset load threshold Lₜₕ, the surface of the electrostatic chuck 40 is exposed to the first plasma. In this manner, it is possible to reduce the residual adsorption force attributable to the intermolecular force between the electrostatic chuck 40 and the semiconductor wafer W.

Others

The technology disclosed herein is not limited to the embodiment described above, and various modifications are still possible within the scope not deviating from the spirit thereof.

For example, in the embodiment described above, the control device 200 performs the plasma process A when the difference ΔL of the load L is greater than the load threshold Lₜₕ, and performs the plasma process B when the difference ΔQ of the electric charge Q is greater than the charge threshold Qₜₕ. However, the technology disclosed herein is not limited thereto. For example, the control device 200 may perform the plasma process A when the load L is greater than a load threshold Lₜₕ′, and perform the plasma process B when the electric charge Q is greater than the charge threshold Qₜₕ′. In such a case, the load threshold Lₜₕ′ is a difference between the initial load L₀ and the load at which the semiconductor wafer W jumps or cracks when the lift pins 81 lift the semiconductor wafer W. Furthermore, the charge threshold Qₜₕ′ is a difference between the initial electric charge Q₀ and the electric charge at which the semiconductor wafer W jumps or cracks when the lift pins 81 lift the semiconductor wafer W.

Furthermore, explained in the embodiment described above is an example of the plasma processing apparatus 1 performing a process using capacitively coupled plasma (CCP), as one example of the plasma source, but the plasma source is not limited thereto. Examples of the plasma source other than the CCP source include an inductively coupled plasma (ICP) source, a microwave-excited surface-wave plasma (SWP) source, an electron cyclotron resonance plasma (ECP) source, and a helicon-wave-excited-plasma (HWP) source.

The embodiment disclosed herein should be rendered exemplary and not as anything restrictive. Actually, the embodiment described above can be implemented in various forms. Furthermore, various forms of omissions, replacements, and modifications of the embodiment described above are still possible, within the scope not deviating from the scope of the appended claims and the essence thereof.

According to various aspects and embodiments disclosed herein, it is possible to reduce the residual adsorption force in an electrostatic chuck.

What is claimed is:

1. A processing method comprising:
a) measuring a load imposed on a lift pin when the lift pin lifts a processed substrate from an electrostatic chuck holding the substrate;
b) calculating a difference of the load based on the measured load, and an initial load imposed on the lift pin when the lift pin lifts the substrate without any residual adsorption force between the electrostatic chuck and the substrate; and
c) exposing a surface of the electrostatic chuck to first plasma when the difference of the load is equal to or greater than a preset first threshold.

2. The processing method according to claim 1, wherein the first threshold is a value smaller than a difference between the initial load and a load imposed on the lift pin at which the substrate jumps when the lift pin lifts the substrate.

3. The processing method according to claim 1, wherein the first plasma is plasma generated by turning nitrogen-containing gas into plasma.

4. The processing method according to claim 1, further comprising:
d) measuring an electric charge in the substrate using a sensor provided to a tip of the lift pin, the tip being on a side that is brought into contact with the substrate, when the lift pin lifts the processed substrate from the electrostatic chuck;
e) calculating a difference of the electric charge based on the measured electric charge and an initial electric charge measured with the sensor while the substrate is not charged; and
f) exposing the surface of the electrostatic chuck to second plasma when the difference of the electric charge is equal to or greater than a preset second threshold.

5. The processing method according to claim 4, wherein the second plasma is plasma generated by turning oxygen- or argon-containing gas into plasma.

6. A placing pedestal comprising:
an electrostatic chuck that holds a substrate;
a lift pin that passes through the electrostatic chuck, and that lifts the substrate held on the electrostatic chuck from the electrostatic chuck;
a driving unit that moves the lift pin up and down; and
a first sensor that measures a load imposed on the lift pin when the substrate is lifted from the electrostatic chuck.

7. The placing pedestal according to claim 6, wherein a second sensor that measures an electric charge of the substrate is provided to a tip of the lift pin, the tip being on a side that is brought into contact with the substrate.

8. A plasma processing apparatus comprising:
a processing container;
an electrostatic chuck that is provided inside the processing container, and that holds a substrate;
a lift pin that passes through the electrostatic chuck, and that lifts the substrate held on the electrostatic chuck from the electrostatic chuck;
a driving unit that moves the lift pin up and down;
a load sensor that measures a load imposed on the lift pin when the substrate is lifted from the electrostatic chuck; and
a control device, wherein
the control device executes:
a) measuring the load imposed on the lift pin when the lift pin lifts a processed substrate from the electrostatic chuck, using the load sensor;
b) calculating a difference of the load based on the measured load, and an initial load imposed on the lift pin when the lift pin lifts the substrate without any residual adsorption force between the electrostatic chuck and the substrate; and
c) exposing a surface of the electrostatic chuck to first plasma when the difference of the load is equal to or greater than a preset first threshold.

9. A non-transitory computer readable recording medium that stores a program for causing a plasma processing apparatus to execute:
a) measuring a load imposed on a lift pin when the lift pin lifts a processed substrate from an electrostatic chuck holding the substrate;
b) calculating a difference of the load based on the measured load, and an initial load imposed on the lift pin when the lift pin lifts the substrate without any residual adsorption force between the electrostatic chuck and the substrate; and
c) exposing a surface of the electrostatic chuck to first plasma when the difference of the load is equal to or greater than a preset first threshold.
